(19) United States
(12) Patent Application Publication
(10) Pub. No.: US 2024/0275126 A1
(43) Pub. Date: Aug. 15, 2024

(54) OPTICAL MODULE AND LIGHT CONTROL DEVICE

(71) Applicant: Sumitomo Electric Industries, Ltd., Osaka (JP)

(72) Inventor: Hiromi NAKANISHI, Osaka (JP)

(73) Assignee: Sumitomo Electric Industries, Ltd., Osaka (JP)

(21) Appl. No.: 18/413,072

(22) Filed: Jan. 16, 2024

(30) Foreign Application Priority Data
Feb. 13, 2023 (JP) 2023-019843

(51) Int. Cl. H01S 5/02326; H01S 5/024; H01S 5/40

(52) U.S. Cl. CPC H01S 5/02326; H01S 5/024; H01S 5/40

(57) ABSTRACT

An optical module includes a first laser diode, a first submount, a first substrate, a first transmission window, a first cap hermetically sealed on the first substrate in such a manner as to cover the first laser diode and the first submount, and a first reflective mirror fixed to the first cap and disposed outside a first space surrounded by the first substrate and the first cap, the first reflective mirror being configured to reflect light transmitted through the first transmission window in a direction inclined with respect to an optical axis direction of the first light.

### CROSS-REFERENCE TO RELATED APPLICATION

This application claims priority based on Japanese Patent Application No. 2023-019843 filed on Feb. 13, 2023, and the entire contents of the Japanese patent application are incorporated herein by reference.

### TECHNICAL FIELD

The present disclosure relates to an optical module and a light control device.

### BACKGROUND

An optical module including a laser diode is disclosed in, for example, PCT International Publication No. WO2019/069775.

### SUMMARY

An optical module according to the present disclosure includes a first laser diode configured to emit first light, a first submount on which the first laser diode is mounted, a first substrate having a first main surface on which the first submount is mounted, a first cap having a first transmission window and hermetically sealed on the first substrate in such a manner as to cover the first laser diode and the first submount, the first transmission window being configured to transmit the first light emitted from the first laser diode, and a first reflective mirror fixed to the first cap and disposed outside a first space surrounded by the first substrate and the first cap, the first reflective mirror being configured to reflect light emitted from the first laser diode and transmitted through the first transmission window in a direction inclined with respect to an optical axis direction of the first light. The first submount has a first-first surface, and a first-second surface intersecting the first-first surface at right angles. The first laser diode is mounted on the first-first surface such that the optical axis direction of the first light is parallel to the first main surface. The first submount is mounted on the first substrate such that the first-second surface and the first main surface face each other.

### BRIEF DESCRIPTION OF THE DRAWINGS

FIG. 1 is a schematic cross-sectional view of a light control device including an optical module in an embodiment 1.

FIG. 2 is an enlarged schematic perspective view of a first laser diode and a first submount, respectively, described below.

FIG. 3 is a schematic cross-sectional view of a light control device including an optical module according to an embodiment 2.

FIG. 4 is a schematic perspective view of a light control device including an optical module according to an embodiment 3.

FIG. 5 is a schematic perspective view of a light control device including an optical module according to an embodiment 4.

FIG. 6 is a schematic perspective view of a light control device including an optical module according to an embodiment 5.

FIG. 7 is a schematic plan view of a light control device including an optical module shown in FIG. 6.

FIG. 8 is an enlarged schematic perspective view showing the vicinity of a first submount included in an optical module according to an embodiment 6.

FIG. 9 is an enlarged schematic perspective view showing the vicinity of a first submount included in an optical module according to an embodiment 7.

FIG. 10 is a schematic perspective view of an optical module included in a light control device according to an embodiment 8.

FIG. 11 is an external perspective view of a state in which a cap of the optical module of FIG. 10 is removed.

FIG. 12 is an external plan view of a state in which a cap of the optical module of FIG. 10 is removed.

### DETAILED DESCRIPTION

The optical module includes a laser diode that emits laser light. The light emitted from the laser diode is desirably emitted in a desired emission direction. In this case, it is desirable to reduce the influence on the light output as much as possible.

It is therefore an object of the present disclosure to provide an optical module capable of emitting light in a desired emission direction while reducing the influence on the light output emitted from the laser diode.

### Description of Embodiments of Present Disclosure

First, embodiments of the present disclosure will be listed and explained. (1) An optical module according to the present disclosure includes a first laser diode configured to emit first light, a first submount on which the first laser diode is mounted, a first substrate having a first main surface on which the first submount is mounted, a first cap having a first transmission window and hermetically sealed on the first substrate in such a manner as to cover the first laser diode and the first submount, the first transmission window being configured to transmit the first light emitted from the first laser diode, and a first reflective mirror fixed to the first cap and disposed outside a first space surrounded by the first substrate and the first cap, the first reflective mirror being configured to reflect light emitted from the first laser diode and transmitted through the first transmission window in a direction inclined with respect to an optical axis direction of the first light. The first submount has a first-first surface, and a first-second surface intersecting the first-first surface at right angles. The first laser diode is mounted on the first-first surface such that the optical axis direction of the first light is parallel to the first main surface. The first submount is mounted on the first substrate such that the first-second surface and the first main surface face each other.

According to such an optical module, since the first laser diode is mounted on the first submount, heat generated when the first laser diode is driven can be efficiently dissipated by the first submount. Since the first laser diode is disposed in the first space hermetically sealed by the first cap and the first substrate, the output of the laser light (first light) emitted from the first laser diode can be stabilized and increased. Since the first cap is provided with the first transmission window, the first light emitted from the first laser diode can be emitted to the outside of the first space through the first transmission window. Further, the first reflective mirror fixed to the first cap and reflecting the first light in a direction inclined with respect to the optical axis direction of the first light is provided outside the first space. Accordingly, the first light transmitted through the first transmission window can be emitted in a desired direction outside the first cap at a changed angle using the first reflective mirror.

The first laser diode is preferably positioned with high accuracy in order to achieve stable emission of light, and is preferably arranged at a predetermined position on the first substrate in advance, hermetically sealed by the first cap, and then fixed on the first substrate by reflow with high-temperature treatment, for example, from the viewpoint of ensuring heat dissipation and characteristics on the electronic circuit. Here, when the emission direction of the first light emitted from the first laser diode is changed to a desired angle, an optical component such as a mirror may be used. Such an optical component is attached to the first substrate after its position is finely adjusted by a bonding material made of resin in consideration of the optical axis of the fixed first laser diode. If the bonding material made of resin for bonding the optical component is present in the first space that is hermetically sealed to form a sealed space, the bonding material cannot withstand a high-temperature reflow environment, causing carbonization of the bonding material and axial misalignment of the optical component. Then, there is a possibility that a problem in strength, a problem in accuracy, or the like may occur in attachment of the optical component. In addition, in the bonding material made of resin exposed to the reflow temperature, a part of molecules constituting the bonding material may be vaporized in the first space to contaminate the inside of the first space, and as a result, there is a possibility that the output of the first laser diode is lowered.

However, according to the above-described configurations, since the first reflective mirror that emits the first light in a desired direction at a changed angle is provided outside the first space, it is not necessary to attach the optical component or the like in the hermetically sealed first space using a bonding material made of resin. Therefore, it is possible to achieve highly accurate positioning of the first laser diode by reflow and to prevent a decrease in output of the first laser diode due to contamination in the hermetically sealed first space. In this case, since the first light can be emitted in a desired direction at a changed an angle by the first reflective mirror fixed to the first cap, the first light transmitted through the transmission window can be emitted in a desired direction outside the first cap at a changed an angle as described above.

Here, the first laser diode is mounted on the first-first surface such that the optical axis direction of the first light is parallel to the first main surface, and the first submount is mounted on the first substrate such that the first-second surface and the first main surface face each other. The above-mentioned optical module is effectively utilized when such application is required. In addition, the first laser diode can sufficiently dissipate heat by the first submount mounted thereon.

As described above, according to such an optical module, it is possible to emit light in a desired emission direction while reducing the influence on the output of the light emitted from the laser diode.

(2) In the above (1), the optical module may further include a fourth laser diode disposed outside the first space and configured to emit fourth light, at least one of a center wavelength band and a polarization direction of the fourth light being different from a center wavelength band or a polarization direction of the first light, a fourth submount disposed outside the first space and on which the fourth laser diode is mounted, a second substrate disposed outside the first space and having a second main surface on which the fourth submount is mounted, a second cap having a second transmission window and hermetically sealed on the second substrate in such a manner as to cover the fourth laser diode and the fourth submount, the second transmission window being configured to transmit the fourth light emitted from the fourth laser diode, and a filter fixed to the second cap and disposed between the first reflective mirror and a scanning mirror in such a manner as to be located outside a second space surrounded by the second substrate and the second cap and outside the first space, the filter being configured to multiplex the first light and the fourth light. In this way, the first light emitted from the first laser diode capable of emitting light in a desired emission direction while reducing the influence on the light output and the fourth light emitted from the fourth laser diode capable of emitting light in a desired emission direction while reducing the influence on the light output are multiplexed to increase the output or emit light of a plurality of colors. Therefore, it is possible to obtain an optical module with improved convenience for a user. Here, the center wavelength band of the light being different means that, for example, the difference between the center wavelength band of the first light and the center wavelength band of the fourth light is more than 30 nm.

(3) In the above (2), the center wavelength band of the first light and the center wavelength band of the fourth light may be the same each other. The polarization direction of the first light may be different from the polarization direction of the fourth light. In this way, it becomes easy to emit and multiplex the first light and the fourth light having the same center wavelength band of light and different polarization directions at the same inclination angle. Then, the first light and the fourth light having different polarization directions are multiplexed, and the output of the first light having the same center wavelength band of light can be increased. Here, the center wavelength band of the light being the same means that the center wavelength band of the first light and the center wavelength band of the fourth light have such a wavelength difference that they have coherence when the polarization directions are the same.

(4) In the above (2) or (3), the fourth submount may have a fourth-first surface on which the fourth laser diode is mounted, a fourth-second surface intersecting the fourth-first surface at right angles, and a fourth-third surface intersecting the fourth-second surface at right angles and positioned such that a space is formed between the fourth-third surface and the fourth-first surface. The fourth submount may be mounted on the second substrate such that the fourth-third surface and the second main surface face each other. The optical module can easily cope with a case where a user desires that the fourth light has such a polarization direction.

(5) In any one of (2) to (4) above, the center wavelength band of the first light and the center wavelength band of the fourth light may be different from each other. In this way, in addition to the first light, the fourth light having a different center wavelength band of light can be emitted in a desired emission direction. In this case, by making the angle of inclination of the first laser diode and the angle of inclination of the fourth laser diode the same, the first light and the fourth light can be emitted at the same angle. Then, it becomes easy to multiplex the emitted first light and fourth light.

(6) In addition, an optical module according to the present disclosure includes a first laser diode configured to emit first light, a first submount on which the first laser diode is mounted, a first substrate having a first main surface on which the first submount is mounted, and a first cap having a first transmission window and hermetically sealed on the first substrate in such a manner as to cover the first laser diode and the first submount, the first transmission window being configured to transmit the first light emitted from the first laser diode. The first submount has a first-first surface, and a first-second surface intersecting the first-first surface at right angles. The first laser diode is mounted on the first-first surface such that an optical axis direction of the first light is inclined with respect to the first main surface. The first submount is mounted on the first substrate such that the first-second surface and the first main surface face each other.

According to such an optical module, since the first laser diode is mounted on the first-first surface such that the optical axis direction of the first light is inclined with respect to the first main surface, the first laser diode can be inclined in a direction in which the first light is desired to be emitted, and the first light can be emitted in a desired direction. Then, by adjusting the angle or the like of the first substrate, the first light transmitted through the first transmission window can be emitted in a desired direction outside the first cap at a changed angles. In addition, it is not necessary to attach the optical component or the like in the hermetically sealed first space using a bonding material made of resin. Therefore, for example, it is possible to achieve highly accurate positioning of the first laser diode by reflow and to prevent a decrease in output of the first laser diode due to contamination in the hermetically sealed first space. Therefore, according to such an optical module, it is possible to emit light in a desired emission direction while reducing the influence on the output of the light emitted from the laser diode.

(7) In the above (6), the first laser diode may have a first end surface being an end surface located on a side from which the first light is emitted, and a second end surface located opposite to the first end surface in a direction in which the first light is emitted. The first end surface may have, when viewed in a direction perpendicular to a first end surface, a first side extending in a thickness direction of the first laser diode and being closer to the first substrate, and a second side located opposite to the first side. When viewed in a direction perpendicular to the first-first surface, one of the first and second sides may overlap the first-first surface, and another one of the first and second sides may project from the first-first surface. In this way, the first light is not blocked by the first-first surface and maintains a strong light intensity, and the heat of the first laser diode can be efficiently dissipated. Therefore, the magnitude of the light output can be maintained and stabilized.

(8) In the above (6) or (7), the optical module may further include a second laser diode configured to emit second light, a center wavelength band of the second light being different from a center wavelength band of the first light, and a second submount disposed adjacent to the first submount and on which the second laser diode is mounted. The second submount may have a second-first surface, and a second-second surface intersecting the second-first surface at right angles. The second laser diode may be mounted on the second-first surface such that an optical axis direction of the second light is inclined with respect to the first main surface. The second submount may be mounted on the first substrate such that the second-second surface and the first main surface face each other. In this way, since the second laser diode that emits the second light whose center wavelength band of light is different from the center wavelength band of the first light is mounted on the second-first surface such that the optical axis direction of the second light is inclined with respect to the first main surface, the second laser diode can be inclined in a direction in which the second light is desired to be emitted, and the second light can be emitted in the desired direction. Then, in addition to the first light, the second light can be emitted in a desired emission direction. In this case, by making the angle of inclination of the first laser diode and the angle of inclination of the second laser diode the same, the first light and the second light can be emitted at the same angle. Then, it becomes easy to multiplex the first light and the second light having different center wavelength bands of light and emit light of a plurality of colors.

(9) In any one of the above (1) to (8), a circuit pattern electrically connected to the first laser diode may be formed on the first substrate. In this way, it is possible to further simplify the routing of the wiring for controlling the operation of the first laser diode. Therefore, it becomes easy to make the device configuration compact.

(10) In the above (9), the first submount may have a first-fourth surface intersecting the first-first surface at right angles and positioned such that a space is formed between the first-fourth surface and the first-second surface. A first pad may be provided on the first submount in such a manner as to extend on the first-first surface and the first-fourth surface. The first laser diode may be electrically connected to the first pad on the first-first surface by a first wire bonding. The circuit pattern may be electrically connected to the first pad on the first-fourth surface by a second wire bonding. In this way, it is possible to shorten the respective wires connecting the first pad and the first laser diode, and the first laser diode and the circuit pattern, and to reduce the wiring resistance of the wires.

(11) In the above (9) or (10), a first pad may be provided on the first submount in such a manner as to extend on the first-first surface and the first-second surface. The first laser diode may be electrically connected to the first pad on the first-first surface by a first wire bonding. The circuit pattern may be electrically connected to the first pad on the first-second surface by being brought into contact with the first pad with an electrically conductive material interposed between the circuit pattern and the first pad. In this way, while the first laser diode and the first pad are electrically connected to each other by the wire, the circuit pattern and the first pad can be electrically connected to each other without using a wire, and the wiring resistance can be further reduced.

(12) A light control device according to the present disclosure includes the optical module according to any one of the above (1) to (11), and a mirror driving mechanism disposed outside the first space and including a scanning mirror on which the first light is incident, the mirror driving mechanism being configured to scan the scanning mirror.

According to such a light control device, it becomes easy to scan the first light emitted from the optical module and draw characters and figures by the laser light. In this case, since the light control device includes the optical module having the above-described configurations capable of emitting light in a desired emission direction while reducing the influence on the output of the light emitted from the laser diode, it is possible to stably draw a high-quality image.

### Details of Embodiments of Present Disclosure

Next, the embodiments of an optical module and a light control device of the present disclosure will be described with reference to the drawings. In the following drawings, the same or corresponding portions are denoted by the same reference numerals, and description thereof will not be repeated.

### Embodiment 1

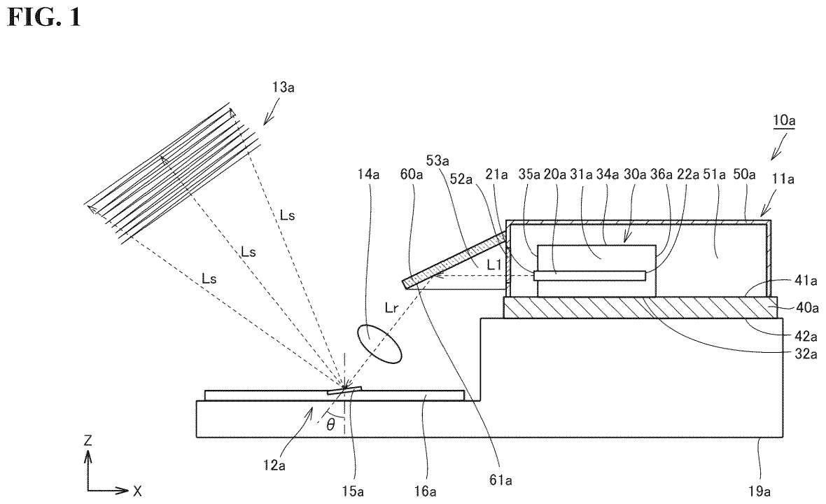

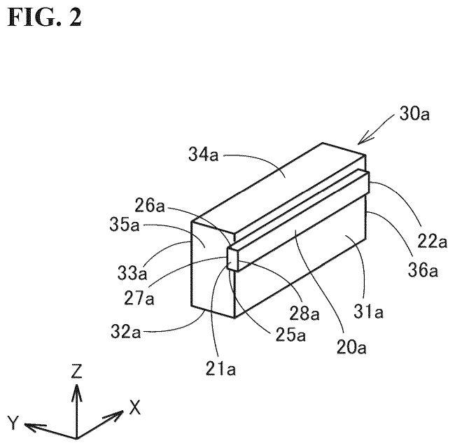

An optical module and a light control device in the embodiment 1 of the present disclosure are described. FIG. 1 is a schematic cross-sectional view of a light control device including an optical module in the embodiment 1. FIG. 2 is an enlarged schematic perspective view of a first laser diode and a first submount, respectively, described below. In FIGS. 1 and 2, an X direction represents an optical axis direction of first light emitted from a first laser diode to be described later, and a Z direction represents a height direction of a light control device. The Z direction is perpendicular to the X direction. The Y direction is a direction perpendicular to each of the X direction and the Z direction. FIG. 1 is a cross-sectional view taken along the X-Z plane. In order to facilitate understanding, some of the constituent members shown in FIG. 1 and hatching are omitted.

Referring to FIGS. 1 and 2, a light control device 10a in the embodiment 1 includes an optical module 11a and a mirror driving mechanism 12a. Light control device 10a includes a base portion 19a supporting optical module 11a and mirror driving mechanism 12a. Light control device 10a emits first light emitted from a first laser diode 20a included in optical module 11a to the outside of light control device 10a while scanning the first light by mirror driving mechanism 12a, and draws an image 13a such as a character or a figure by using the first light emitted from first laser diode 20a.

Optical module 11a includes first laser diode 20a, a first submount 30a on which first laser diode 20a is mounted, a first substrate 40a on which first submount 30a is mounted, a first cap 50a, and a first reflective mirror 60a. First laser diode 20a emits the first light. First laser diode 20a includes a first end surface 21a, which is an end surface on which the first light is emitted, and a second end surface 22a, which is located opposite to first end surface 21a in a direction in which the first light is emitted. When viewed in a direction perpendicular to first end surface 21a, first end surface 21a includes a first side 25a being closer to first substrate 40a (parallel to a thickness direction of first laser diode 20a and the Y direction), a second side 26a located opposite to first side 25a, a third side 27a (parallel to first-first surface 31a) located near a first-first surface 31a (described later), and a fourth side 28a located opposite to third side 27a. The first light is emitted from third side 27a. Here, being emitted from third side 27a does not strictly mean being emitted only from third side 27a, but includes being emitted from the vicinity of third side 27a (the same applies to the other embodiments). The first light emitted from first laser diode 20a travels along a first optical path L1. First optical path L1 extends along an optical axis direction (X direction) of the first light. The first light is, for example, red light having a center wavelength band including 638 nm.

First submount 30a has a rectangular parallelepiped shape. First submount 30a includes first-first surface 31a, a first-second surface 32a, a first-third surface 33a, a first-fourth surface 34a, a first-fifth surface 35a, and a first-sixth surface 36a. First-second surface 32a, first-fourth surface 34a, first-fifth surface 35a, and first-sixth surface 36a each intersect first-first surface 31a at right angles. First-fifth surface 35a intersects first-second surface 32a and first-fourth surface 34a at right angles respectively. First-sixth surface 36a intersects first-second surface 32a and first-fourth surface 34a at right angles, respectively. First-first surface 31a and first-third surface 33a are parallel to the X-Z plane. First-second surface 32a and first-fourth surface 34a are parallel to the X-Y plane. First-fifth surface 35a and first-sixth surface 36a are parallel to the Y-Z plane.

First laser diode 20a is mounted on first-first surface 31a in first submount 30a. That is, first laser diode 20a is attached to a so-called side surface of first submount 30a. By being attached in this way, for example, the polarization direction of the first light becomes the Z direction (vertical direction).

First laser diode 20a is mounted such that first end surface 21a is positioned at the same side of first-fifth surface 35a. First laser diode 20a is disposed on first submount 30a such that first end surface 21a projects from first-first surface 31a when viewed in the Y direction. Specifically, first laser diode 20a is disposed such that first end surface 21a projects toward first-fifth surface 35a. With this disposition, it is possible to prevent the first light from being blocked by first submount 30a and to efficiently emit the first light.

First substrate 40a has a flat plate shape and includes a first main surface 41a located at one of the end surfaces in the thickness direction which is the Z direction. First submount 30a is mounted on first main surface 41a. First submount 30a is mounted on first substrate 40a such that first-second surface 32a and first main surface 41a face each other. In this case, first submount 30a is fixed on first main surface 41a via a bonding material such as solder. First laser diode 20a is mounted on first-first surface 31a such that the optical axis direction (X direction) of the first light is parallel to first main surface 41a.

First cap 50a is hermetically sealed on first substrate 40a. First cap 50a covers first laser diode 20a and first submount 30a. First cap 50a forms a first space 51a between first substrate 40a and first cap 50a. That is, first laser diode 20a and first submount 30a are disposed in first space 51a. First space 51a is a decompressed space. First cap 50a has a first transmission window 52a. First transmission window 52a is made of glass, for example, and transmits the first light emitted from first laser diode 20a. First transmission window 52a is provided in the emission direction of the first light emitted from first laser diode 20a.

First reflective mirror 60a is disposed outside first space 51a. First cap 50a is formed with a protruding portion 53a protruding toward a side from which the first light is emitted. Protruding portion 53a is disposed outside first space 51a. First reflective mirror 60a is fixed to first cap 50a. Specifically, first reflective mirror 60a is attached to protruding portion 53a. First reflective mirror 60a is mounted such that a first reflective surface 61a is disposed on first optical path L1 transmitted through first transmission window 52a. First reflective mirror 60a is disposed such that first reflective surface 61a is inclined with respect to an optical axis direction (X direction) of the first light. First reflective mirror 60a reflects the first light transmitted through first transmission window 52a in a direction inclined with respect to the optical axis direction of the first light. The first light reflected by first reflective mirror 60a travels along an optical path Lr.

The first light emitted from first laser diode 20a and traveling along first optical path L1 passes through first space 51a, is transmitted through first transmission window 52a, and is emitted to the outside of first space 51a. The first light emitted to the outside of first space 51a travels along first optical path L1 and reaches first reflective surface 61a of first reflective mirror 60a. Since first reflective surface 61a is inclined with respect to the optical axis direction of the first light, the first light is reflected by first reflective surface 61a along optical path Lr while changing an angle with respect to the optical axis of the first light.

Optical module 11a includes a converging lens 14a that converges the laser light that is diffused light. Converging lens 14a is disposed on optical path Lr. The first light traveling along optical path Lr is converged by converging lens 14a. The first light passing through converging lens 14a travels along optical path Lr and reaches mirror driving mechanism 12a.

Next, the configurations of mirror driving mechanism 12a will be briefly described. Mirror driving mechanism 12a is disposed outside first space 51a. Mirror driving mechanism 12a includes a scanning mirror 15a on which the first light is incident and a support portion 16a supporting scanning mirror 15a. Scanning mirror 15a is swingably supported by support portion 16a. Mirror driving mechanism 12a causes scanning mirror 15a to swing at a high speed when light control device 10a is in operation.

The first light traveling along optical path Lr is incident on scanning mirror 15a. An incident angle θ of the first light incident on scanning mirror 15a is, for example, 45 degrees. The first light reflected by scanning mirror 15a swing at a high speed travels along an optical path Ls and draws image 13a by the laser light outside light control device 10a.

Here, a method of manufacturing optical module 11a described above will be briefly described. First, first substrate 40a is prepared, and first submount 30a having first laser diode 20a mounted on first-first surface 31a is mounted on first main surface 41a of first substrate 40a. In this case, a bonding material such as solder is disposed between first-second surface 32a of first submount 30a and first main surface 41a. Thereafter, first cap 50a is put on first main surface 41a. At this time, first cap 50a is disposed on first main surface 41a such that the first light emitted from first laser diode 20a is emitted from first transmission window 52a. Then, first cap 50a is hermetically sealed and fixed to first substrate 40a. Thereafter, the solder is melted to fix first submount 30a on which first laser diode 20a is mounted on first main surface 41a of first substrate 40a. Thereafter, the mounting position such as the inclination angle of first reflective mirror 60a is adjusted as necessary.

The positions of converging lens 14a and mirror driving mechanism 12a are adjusted and disposed in accordance with optical path Lr and the position where image 13a is drawn using optical module 11a manufactured as described above. In this way, light control device 10a is manufactured.

According to optical module 11a, since first laser diode 20a is mounted on first submount 30a, heat generated when first laser diode 20a is driven can be efficiently dissipated by first submount 30a. Since first laser diode 20a is disposed in first space 51a hermetically sealed by first cap 50a and first substrate 40a, the output of the laser light emitted by first laser diode 20a can be stabilized and increased. Since first cap 50a is provided with first transmission window 52a, the first light emitted from first laser diode 20a can be emitted to the outside of first space 51a through first transmission window 52a. Since first reflective mirror 60a fixed to first cap 50a and reflecting the first light in a direction inclined with respect to the optical axis direction of the first light is provided outside first space 51a, the first light transmitted through first transmission window 52a can be emitted in a desired direction outside first cap 50a at a changed angle.

In addition, since first reflective mirror 60a for emitting the first light in a desired direction at a changed angle is provided outside first space 51a, it is not necessary to attach an optical component or the like in the hermetically sealed first space 51a using a bonding material made of resin. Therefore, it is possible to achieve highly accurate positioning of first laser diode 20a and to prevent a decrease in output of first laser diode 20a due to contamination in the hermetically sealed first space 51a. In this case, since the first light can be emitted in a desired direction at a changed an angle by first reflective mirror 60a fixed to first cap 50a, the first light transmitted through first transmission window 52a can be emitted in a desired direction outside first cap 50a at a changed an angle described above.

In addition, first laser diode 20a is mounted on first-first surface 31a such that the optical axis directions of the first light is parallel to first main surface 41a, and first submount 30a is mounted on first substrate 40a such that first-second surface 32a and first main surface 41a face each other. Therefore, it is effectively used when such a use is required. In addition, first laser diode 20a can sufficiently dissipate heat by first submount 30a mounted thereon.

According to optical module 11a, it is possible to emit light in a desired emission direction while reducing the influence on the output of the light emitted from first laser diode 20a.

In addition, according to light control device 10a, it becomes easy to scan the first light emitted from optical module 11a and draw characters and figures by the laser light. In this case, since light control device 10a includes optical module 11a having the above-described configurations capable of emitting light in a desired emission direction while reducing the influence on the output of the first light emitted from first laser diode 20a, it is possible to stably draw a high-quality image.

In the embodiment, optical module 11a may be configured to include a second laser diode that emits green light and a third laser diode that emits blue light in addition to red first laser diode 20a. In this case, a second submount on which the second laser diode is mounted and a third submount on which the third laser diode is mounted may be provided separately from first submount 30a. That is, optical module 11a may include the second submount which is provided separately from first submount 30a and on which the second laser diode is mounted and the third submount which is provided separately from first submount 30a and on which the third laser diode is mounted. In this way, optical module 11a can emit light of each color.

In addition, a light control device including optical module 11a may not include mirror driving mechanism 12a and may include another configuration. For example, the light control device can be used as a display device using monochromaticity, high brightness, coherence, and linear polarization of light emitted from optical module 11a.

### Embodiment 2

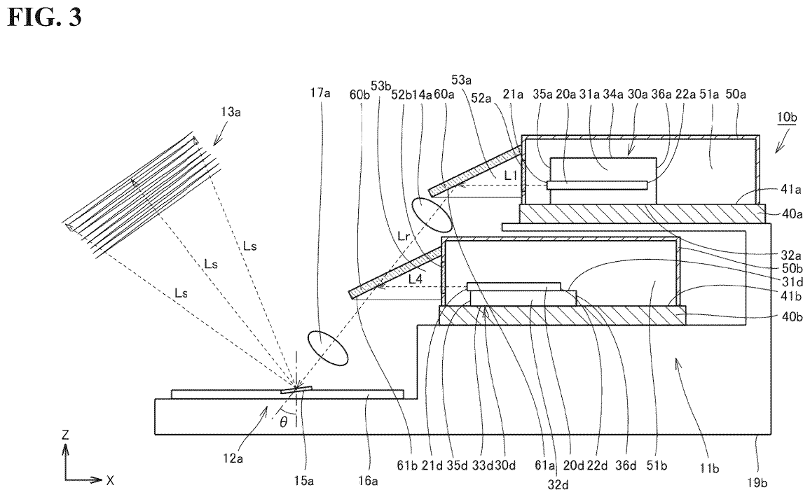

An embodiment 2 according to another embodiment will be described. FIG. 3 is a schematic cross-sectional view of a light control device including an optical module according to the embodiment 2. The light control device in the embodiment 2 basically has the same configurations as those in the case of the embodiment 1 and produces the same effect. However, the light control device of the embodiment 2 is different from that of the embodiment 1 in the configurations including a fourth laser diode and the like.

Referring to FIG. 3, a light control device 10b in the embodiment 2 includes an optical module 11b and mirror driving mechanism 12a. Light control device 10b includes a base portion 19b supporting optical module 11b and mirror driving mechanism 12a. Optical module 11b includes first laser diode 20a, first submount 30a on which first laser diode 20a is mounted, first substrate 40a on which first submount 30a is mounted, first cap 50a, and first reflective mirror 60a. Optical module 11b includes a fourth laser diode 20d disposed outside first space 51a and emitting fourth light having a polarization direction different from that of the first light, a fourth submount 30d disposed outside first space 51a and on which fourth laser diode 20d is mounted, a second substrate 40b disposed outside first space 51a and having a second main surface 41b on which fourth submount 30d is mounted, a second cap 50b having a second transmission window 52b and hermetically sealed on second substrate 40b in such a manner as to cover fourth laser diode 20d and fourth submount 30d, second transmission window 52b being configured to transmit the fourth light emitted from fourth laser diode 20d, and a filter 60b fixed to second cap 50b and disposed between first reflective mirror 60a and scanning mirror 15a in a such a manner as to be located outside a second space 51b surrounded by second substrate 40b and second cap 50b and outside first space 51a, filter 60b being configured to multiplex the first light and the fourth light. Second cap 50b has a protruding portion 53b. Since the configurations of second substrate 40b are the same as those of first substrate 40a, the description thereof will be omitted.

Fourth laser diode 20d emits fourth light. The center wavelength band of the fourth light emitted from fourth laser diode 20d is the same as the center wavelength band of the first light emitted from first laser diode 20a. Fourth laser diode 20d includes a first end surface 21b, being an end surface located on a side from which the fourth light is emitted, and a second end surface 22b located opposite to first end surface 21b in a direction in which the second light is emitted. The fourth light emitted from fourth laser diode 20d travels along a fourth optical path L4. Fourth optical path L4 extends along an optical axis direction (X direction) of the fourth light.

Similar to first submount 30a, fourth submount 30d includes a fourth-first surface 31d, a fourth-second surface 32d, a fourth-third surface 33d, a fourth-fourth surface, a fourth-fifth surface 35d, and a fourth-sixth surface 36d.

Fourth laser diode 20d is mounted on fourth-first surface 31d in fourth submount 30d. Fourth submount 30d is mounted on second main surface 41b such that fourth-third surface 33d and second main surface 41b face each other. In this case, fourth laser diode 20d is attached on a so-called upper surface of fourth submount 30d. By being attached in this way, the polarization direction of the fourth light emitted from fourth laser diode 20d becomes the Y direction (horizontal direction). That is, the polarization direction (Z direction) of the first light emitted from first laser diode 20a is perpendicular to the polarization direction (Y direction) of the fourth light emitted from fourth laser diode 20d.

Filter 60b transmits the first light emitted from first laser diode 20a and reflects the fourth light emitted from fourth laser diode 20d on a second reflective surface 61b. That is, filter 60b is configured to transmit the first light emitted from first laser diode 20a, reflect the fourth light emitted from fourth laser diode 20d, and multiplex the first light emitted from first laser diode 20a and the fourth light emitted from fourth laser diode 20d.

Optical module 11b includes a collimating lens 17a that converts the spot size of the multiplexed light. The multiplexed light transmitted through collimating lens 17a is collimation-converted. The collimation-converted multiplexed light reaches scanning mirror 15a. Image 13a is drawn by mirror driving mechanism 12a using the multiplexed light.

According to the embodiment, it becomes easy to emit the first light having the same center wavelength band of light and different polarization directions at the same inclination angle and multiplex them. Then, the first lights having different polarization directions are multiplexed, and the output of the first light having the same center wavelength band of light can be increased.

In the embodiment described above, the configuration may be adopted in which the disposition of fourth laser diode 20d and fourth submount 30d is the same as the disposition of first laser diode 20a and first submount 30a, and the center wavelength band of the first light emitted from first laser diode 20a is different from the center wavelength band of the fourth light emitted from fourth laser diode 20d. Then, filter 60b may transmit the first light emitted from first laser diode 20a and reflect the fourth light emitted from fourth laser diode 20d. Such optical module 11b can emit light in a desired emission direction while reducing the influence on the light output, and can easily multiplex light having different center wavelength bands of light to emit light of a plurality of colors.

### Embodiment 3

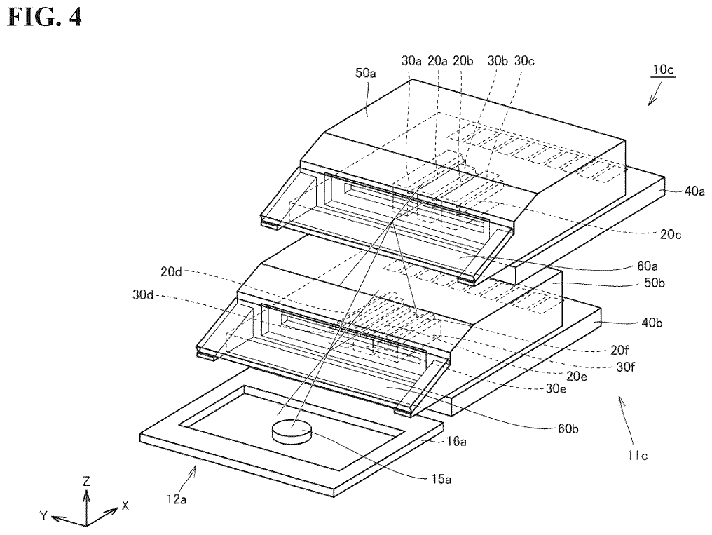

An embodiment 3 according to another embodiment will be described. FIG. 4 is a schematic perspective view of a light control device including an optical module according to the embodiment 3. The light control device in the embodiment 3 basically has the same configurations as those in the case of the embodiment 2 and produces the same effect. However, the light control device of the embodiment 3 is different from that of the embodiment 2 in the configuration including a plurality of laser diodes having different center wavelength bands of light.

Referring to FIG. 4, a light control device 10c of the embodiment 3 includes an optical module 11c and mirror driving mechanism 12a. Optical module 11c includes first laser diode 20a that emits red light, a second laser diode 20b whose center wavelength band of light is 532 nm and that green light, a third laser diode 20c whose center wavelength band of light is 450 nm and that emits blue light, first submount 30a on which first laser diode 20a is mounted, a second submount 30b on which second laser diode 20b is mounted, a third submount 30c on which third laser diode 20c is mounted, first substrate 40a on which first submount 30a, second submount 30b, and third submount 30c are mounted, first cap 50a, and first reflective mirror 60a. In the embodiment, unlike the case of the embodiment 2, second laser diode 20b is different from first laser diode 20a not in the polarization direction but in the center wavelength band of light. First submount 30a, second submount 30b, and third submount 30c are disposed adjacent to each other in the Y direction. Optical module 11c includes fourth laser diode 20d that emits red light, a fifth laser diode 20e that emits green light, a sixth laser diode 20f that emits blue light, fourth submount 30d on which fourth laser diode 20d is mounted, a fifth submount 30e on which fifth laser diode 20e is mounted, a sixth submount 30f on which sixth laser diode 20f is mounted, second substrate 40b on which fourth submount 30d, fifth submount 30e, and sixth submount 30f are mounted, second cap 50b, and filter 60b. Fourth submount 30d, fifth submount 30e, and sixth submount 30f are disposed adjacent to each other in the Y direction.

Second laser diode 20b and third laser diode 20c are different from first laser diode 20a only in the center wavelength band of light, and the other configurations are the same. Fifth laser diode 20e and sixth laser diode 20f are different from fourth laser diode 20d only in the center wavelength band of light, and other configurations are the same.

Filter 60b transmits red light, green light, and blue light with polarization direction in the Z direction. Filter 60b reflects red light, green light, and blue light with polarization direction in the Y direction.

Since light control device 10c including such optical module 11c outputs the multiplexed light in which the polarization directions of the respective colors are vertically multiplexed, it is possible to draw a full-color image with high output.

### Embodiment 4

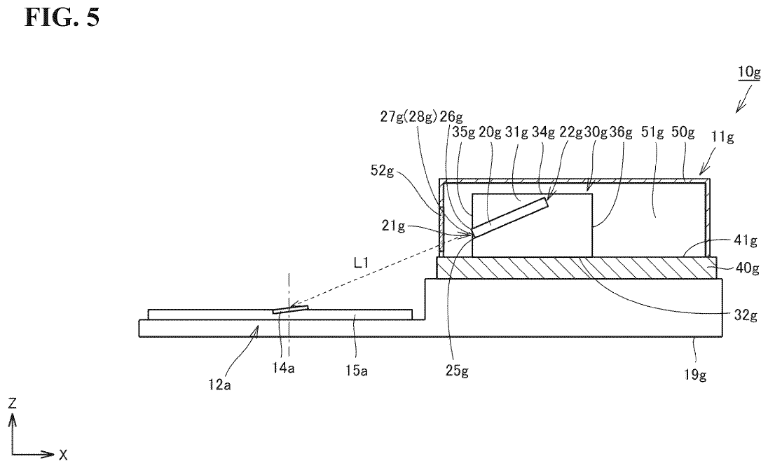

An embodiment 4 according to another embodiment will be described. FIG. 5 is a schematic perspective view of a light control device including an optical module according to the embodiment 4. The light control device in the embodiment 4 basically has the same configurations as those in the case of the embodiment 1 and produces the same effect. However, the light control device of the embodiment 4 is different from that of the embodiment 1 in that the first laser diode is inclined.

Referring to FIG. 5, a light control device 10g in the embodiment 4 includes an optical module 11g and mirror driving mechanism 12a. Light control device 10g includes a base portion 19g supporting optical module 11g and mirror driving mechanism 12a. Optical module 11g includes a first laser diode 20g, a first submount 30g on which first laser diode 20g is mounted, a first substrate 40g on which first submount 30g is mounted, a first cap 50g. First substrate 40g includes a first main surface 41g. Since the configuration of first substrate 40g is the same as that of first substrate 40a, the description thereof will be omitted.

Similar to first submount 30a, first submount 30g includes a first-first surface 31g, a first-second surface 32g, a first-third surface 33g, a first-fourth surface 34g, a first-fifth surface 35g, and a first-sixth surface 36g. First laser diode 20g is mounted on first-first surface 31g in first submount 30g. That is, first laser diode 20g is attached to a so-called side surface of first submount 30g. First submount 30g is mounted on first substrate 40g such that first-second surface 32g and first main surface 41g face each other. First laser diode 20g is mounted on first-first surface 31g such that the optical axis direction of the first light is inclined with respect to first main surface 41g.

First laser diode 20g emits the first light. First laser diode 20g includes first end surface 21g being an end surface on a side from which the first light is emitted, and a second end surface 22g located opposite to first end surface 21g in a direction in which the first light is emitted. When viewed in a direction perpendicular to first end surface 21g (Y direction), first end surface 21g includes a first side 25g extending in a thickness direction of first laser diode 20g and being closer to first substrate 40a (parallel to the Y direction), a second side 26g located opposite to first side 25g (parallel to the Y direction), a third side 27g located near first-first surface 31g (parallel to first-first surface 31g), and a fourth side 28g located opposite to third side 27g (parallel to first-first surface 31g). The first light is emitted from third side 27g. The first light emitted from first laser diode 20g travels along first optical path L1. First optical path L1 extends along a direction inclined with respect to first main surface 41g. When viewed in the Y direction, first side 25g overlaps first-first surface 31g, and second side 26g projects from first-first surface 31g.

According to the embodiment, first side 25g overlaps first-first surface 31g, and second side 26g projects from first-first surface 31g. With these configurations, the first light is not blocked by first-first surface 31g and maintains a strong light intensity, and the heat of first laser diode 20g can be efficiently dissipated. Therefore, the magnitude of the light output can be maintained and stabilized.

First cap 50g is hermetically sealed on first substrate 40g. First cap 50g covers first laser diode 20g and first submount 30g. A first space 51g is formed between first cap 50g and first substrate 40g. That is, first laser diode 20g and first submount 30g are disposed in first space 51g. First cap 50g has a first transmission window 52g. First transmission window 52g is made of glass, for example, and transmits the first light emitted from first laser diode 20g. First transmission window 52g is provided in the emission direction of the first light emitted from first laser diode 20g Unlike first cap 50a of the embodiment 1, first cap 50g does not have a protruding portion. Also, optical module 11g does not include a first reflective mirror.

The first light emitted from first laser diode 20g and traveling along first optical path L1 passes through first space 51g, is transmitted through first transmission window 52g, and is emitted to the outside of first space 51g. The first light emitted to the outside of first space 51g travels along first optical path L1 and reaches scanning mirror 15a of mirror driving mechanism 12a. An incident angle at this time is lower (smaller) than in the case of the embodiment 1. Subsequent operations and the like are the same as those of the embodiment 1.

According to the embodiment, since first laser diode 20g is mounted on first-first surface 31g such that the optical axis direction of the first light is inclined with respect to first main surface 41g, first laser diode 20g can be inclined in a direction in which first light is desired to be emitted, and the first light can be emitted in the desired direction. Therefore, according to optical module 11g, it is possible to emit light in a desired emission direction while reducing the influence on the output of light emitted from first laser diode 20g.

In the embodiment, a configuration may be adopted in which a second laser diode that emits green light and a third laser diode that emits blue light are included. Similarly to first laser diode 20g, the second laser diode and the third laser diode may be mounted such that the optical axis direction of each light is inclined with respect to first main surface 41g.

### Embodiment 5

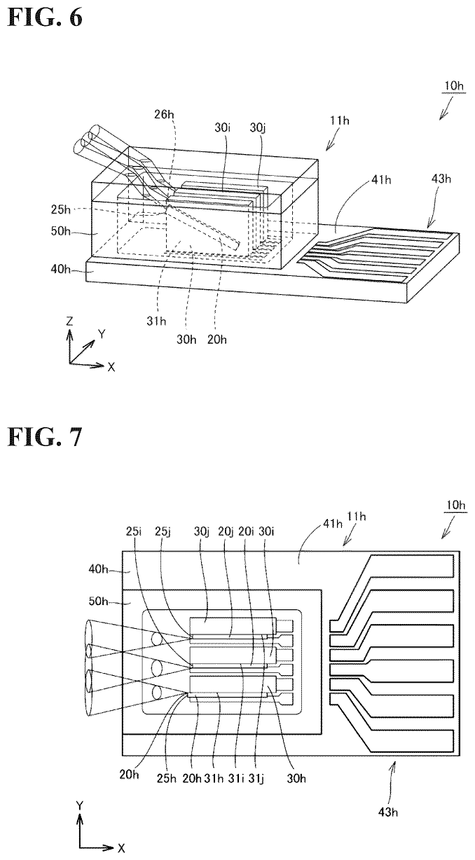

An embodiment 5 according to another embodiment will be described. FIG. 6 is a schematic perspective view of a light control device including an optical module according to the embodiment 5. FIG. 7 is a schematic plan view of a light control device including an optical module shown in FIG. 6. The light control device in the embodiment 5 basically has the same configurations as those in the case of the embodiment 4 and produces the same effect. However, the light control device of the embodiment 5 is different from that of the embodiment 4 in the configuration including the third laser diode and the like.

Referring to FIGS. 6 and 7, a light control device 10h in the embodiment 5 includes an optical module 11h. Optical module 11h includes a first laser diode 20h that emits red light, a second laser diode 20i that emits green light, a third laser diode 20j that emits blue light, a first submount 30h on which first laser diode 20h is mounted, a second submount 30i on which second laser diode 20i is mounted, a third submount 30j on which third laser diode 20j is mounted, a first substrate 40h on which first submount 30h, second submount 30i, and third submount 30j are mounted, and a first cap 50h. A circuit pattern 43h electrically connected to first laser diode 20h, second laser diode 20i, and third laser diode 20j is formed on first substrate 40h. Circuit pattern 43h is formed on a first main surface 41h. Wires that electrically connect circuit pattern 43h to first laser diode 20h, second laser diode 20i, and third laser diode 20j are not shown.

First laser diode 20h is mounted on a first-first surface 31h of first submount 30h such that the optical axis direction of the first light is inclined with respect to first main surface 41h. Second laser diode 20i is mounted on a third-first surface 31i of second submount 30i such that the optical axis direction of the second light is inclined with respect to first main surface 41h. Third laser diode 20j is mounted on a third-first surface 31j of third submount 30j such that the optical axis direction of the third light is inclined with respect to first main surface 41h. The angle of inclination of the first light, the angle of inclination of the second light, and the angle of inclination of the third light are the same. The first light is emitted from a third side 27h. When viewed from the Y direction, a second side 26h of first laser diode 20h overlaps first-first surface 31h, and a first side 25h closer to first substrate 40h projects from first-first surface 31h. With this disposition, it is possible to prevent the first light from being blocked by first submount 30h and to efficiently emit the first light. In particular, with respect to red first laser diode 20h whose temperature deterioration is large, the first light is not blocked by first-first surface 31h and maintains a strong light intensity, and the heat of first laser diode 20h can be efficiently radiated. Therefore, the magnitude of the light output can be maintained and stabilized. When viewed from the Y direction, a first side 25i of second laser diode 20i and a first side 25j of third laser diode 20j overlap a first-first surface 31i and first-first surface 31j, respectively. That is, when viewed from the Y direction, first side 25i and the third side of second laser diode 20i and first side 25j and the third side of third laser diode 20j overlap first-first surface 31i and first-first surface 31j, respectively. This disposition allows efficient light emission for green second laser diode 20i and blue third laser diode 20j which are relatively highly deteriorated by temperature.

According to optical module 11h, it is possible to emit light in a desired emission direction for each of first laser diode 20h, second laser diode 20i, and third laser diode 20j while reducing the influence on the output of the light emitted from each of first laser diode 20h, second laser diode 20i, and third laser diode 20j. In this case, by multiplexing the red light emitted from first laser diode 20h, the green light emitted from second laser diode 20i, and the blue light emitted from third laser diode 20j, it is possible to achieve drawing by full-color laser light.

In the embodiment, circuit pattern 43h electrically connected to first laser diode 20h and the like is formed on first substrate 40h. Therefore, it is possible to further simplify the routing of the wiring for controlling the operation of first laser diode 20h and the like. Therefore, it becomes easy to make the device configuration compact.

### Embodiment 6

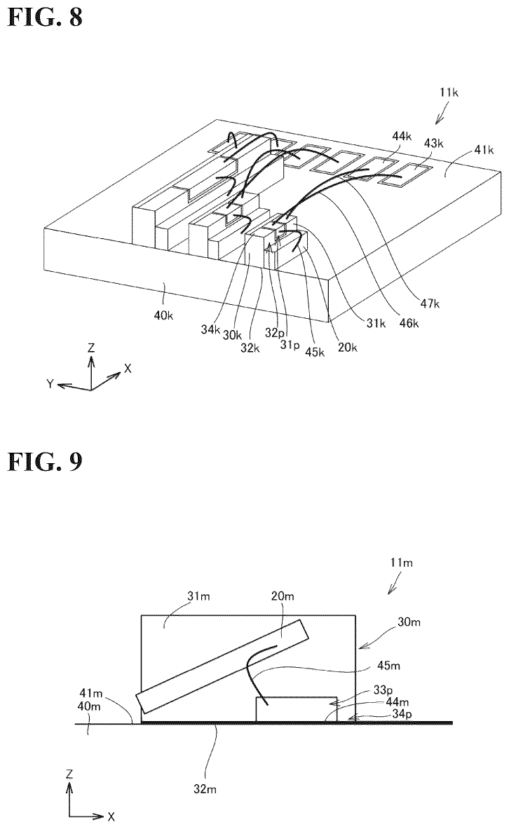

An embodiment 6 according to another embodiment will be described. FIG. 8 is an enlarged schematic perspective view showing the vicinity of the first submount included in an optical module according to the embodiment 6. The optical module in the embodiment 6 basically has the same configurations as those in the embodiment 1, and produces the same effect. However, the optical module of the embodiment 6 is different from that of the embodiment 1 in that the first laser diode is connected to the circuit pattern by a wire.

Referring to FIG. 8, an optical module 11k includes a first submount 30k. First submount 30k mounted on a first main surface 41k of a first substrate 40k includes a first-fourth surface 34k intersecting a first-first surface 31k at right angles and positioned such that a space is formed between first-fourth surface 34k and first-second surface 32k. A first pad 31p is provided on first submount 30k in such a manner as to extend on first-first surface 31k and first-fourth surface 34k. A second pad 32p is provided on first submount 30k in such a manner as to extend on first-first surface 31k and first-fourth surface 34k. In first pad 31p, first-first surface 31k and a first laser diode 20k are electrically connected by a wire 45k using wire bonding. Second pad 32p is electrically connected to the lower surface of first laser diode 20k. A circuit pattern 43k is electrically connected to first pad 31p on first-fourth surface 34k by a wire 46k using wire bonding. A circuit pattern 44k is electrically connected to first-fourth surface 34k on first submount 30k by a wire 47k using wire bonding. Therefore, each wire connecting first pad 31p to first laser diode 20k and first laser diode 20k to circuit pattern 43k can be shortened, and the wiring resistance of the wire can be reduced.

In the embodiment described above, the configuration may be adopted in which circuit pattern 44k extend in the X direction and is electrically in contact with first-second surface 32k of first submount 30k. In this way, wire 47k can be omitted and the number of wires can be reduced.

### Embodiment 7

An embodiment 7 according to another embodiment will be described. FIG. 9 is an enlarged schematic perspective view showing the vicinity of the first submount included in an optical module according to the embodiment 7. The optical module in the embodiment 7 basically has the same configurations as those in the case of the embodiment 6, and produces the same effect. However, the optical module of the embodiment 7 is different from that of the embodiment 6 in that the first laser diode is connected to the first pad by a wire.

Referring to FIG. 9, an optical module 11m includes a first submount 30m. A first pad 33p is provided on first submount 30m mounted on a first main surface 41m of a first substrate 40m in such a manner as to extend on a first-first surface 31m and a first-second surface 32m. A second pad 34p is provided on first submount 30m in such a manner as to extend on first-first surface 31m and first-second surface 32m. In first pad 33p, first-first surface 31m and a first laser diode 20m are electrically connected by a wire 45m by wire bonding. Second pad 34p is electrically connected to the lower surface of first laser diode 20m. A circuit pattern 44m is electrically connected to first pad 33p on first-second surface 32m via an electrically conductive material. Therefore, while first laser diode 20m and first pad 33p are electrically connected to each other by wire 45m, circuit pattern 44m can be electrically connected to first pad 33p and first submount 30m without using a wire, thereby further reducing the wiring resistance. (Embodiment 8)

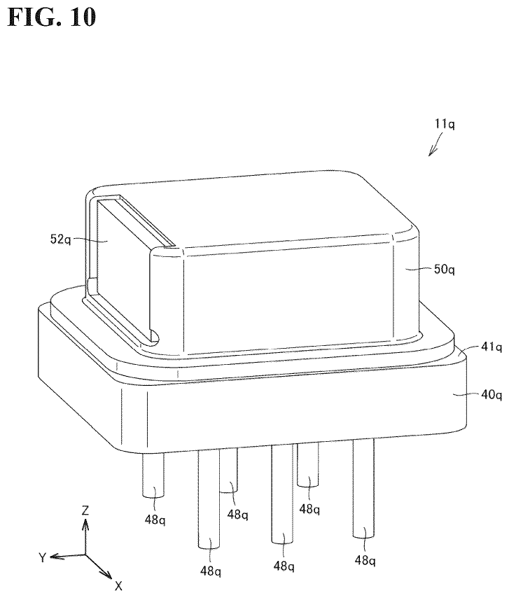

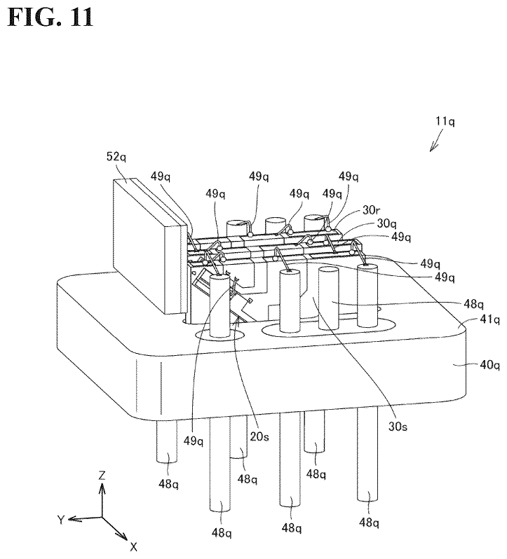

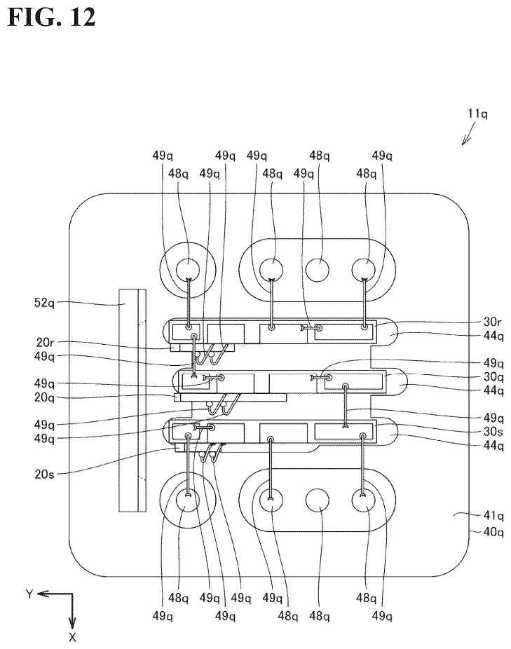

An embodiment 8 according to another embodiment will be described. FIG. 10 is a schematic perspective view of an optical module included in a light control device according to the embodiment 8. FIG. 11 is an external perspective view of an optical module shown in FIG. 10 with a cap removed. FIG. 12 is an external plan view of a state in which the cap of the optical module shown in FIG. 10 is removed. The optical module included in the light control device in the embodiment 8 basically has the same configurations as those in the case of the embodiment 1 and produces the same effect. However, the optical module included in the light control device of the embodiment 8 is different from that of the embodiment 1 in the configuration including the second laser diode and the like. For ease of understanding, the first transmission window is shown in FIGS. 11 and 12.

Referring to FIGS. 10, 11 and 12, an optical module 11q included in the light control device of the embodiment 8 includes a first laser diode 20q that emits red light, a second laser diode 20r that emits green light, a third laser diode 20s that emits blue light, a first submount 30q on which first laser diode 20q is mounted, a second submount 30r on which second laser diode 20r is mounted, a third submount 30s on which third laser diode 20s is mounted, a first substrate 40q on which first submount 30q, second submount 30r and third submount 30s are mounted, and a first cap 50q. A circuit pattern 44q is provided on a first main surface 41q of first substrate 40q. Optical module 11q includes a plurality of lead pins 48q attached to first substrate 40q so as to extend in the Z direction. A circuit pattern 43q electrically connected to first laser diode 20q, second laser diode 20r, and third laser diode 20s is formed on first substrate 40q. Circuit pattern 43q is formed on first main surface 41q. First laser diode 20q, second laser diode 20r, and third laser diode 20s are electrically connected to a plurality of lead pins 48q and the like using the plurality of wires 49q. Each of first laser diode 20q, second laser diode 20r, and third laser diode 20s is inclined with respect to first main surface 41q. First cap 50q is provided with a first transmission window 52q, and red light, green light, and blue light are emitted to the outside of optical module 11q through first transmission window 52q.

In this way, each laser diode can be electrically connected to the outside using the plurality of lead pins 48q and can be controlled.

It should be understood that the embodiments disclosed herein are illustrative in all respects and are not restrictive in any respect. The scope of the present invention is defined not by the above description but by the claims, and is intended to include all modifications within the meaning and scope equivalent to the claims.

What is claimed is:

1. An optical module comprising:
a first laser diode configured to emit first light;
a first submount on which the first laser diode is mounted;
a first substrate having a first main surface on which the first submount is mounted;
a first cap having a first transmission window and hermetically sealed on the first substrate in such a manner as to cover the first laser diode and the first submount, the first transmission window being configured to transmit the first light emitted from the first laser diode; and
a first reflective mirror fixed to the first cap and disposed outside a first space surrounded by the first substrate and the first cap, the first reflective mirror being configured to reflect light emitted from the first laser diode and transmitted through the first transmission window in a direction inclined with respect to an optical axis direction of the first light,
wherein the first submount has
a first-first surface, and
a first-second surface intersecting the first-first surface at right angles,
wherein the first laser diode is mounted on the first-first surface such that the optical axis direction of the first light is parallel to the first main surface, and
wherein the first submount is mounted on the first substrate such that the first-second surface and the first main surface face each other.

2. The optical module according to claim 1, further comprising:
a fourth laser diode disposed outside the first space and configured to emit fourth light, at least one of a center wavelength band and a polarization direction of the fourth light being different from a center wavelength band or a polarization direction of the first light;
a fourth submount disposed outside the first space and on which the fourth laser diode is mounted;
a second substrate disposed outside the first space and having a second main surface on which the fourth submount is mounted;
a second cap having a second transmission window and hermetically sealed on the second substrate in such a manner as to cover the fourth laser diode and the fourth submount, the second transmission window being configured to transmit the fourth light emitted from the fourth laser diode; and
a filter fixed to the second cap and disposed between the first reflective mirror and a scanning mirror in such a manner as to be located outside a second space surrounded by the second substrate and the second cap and outside the first space, the filter being configured to multiplex the first light and the fourth light.

3. The optical module according to claim 2,
wherein the center wavelength band of the first light and the center wavelength band of the fourth light are the same each other, and
wherein the polarization direction of the first light is different from the polarization direction of the fourth light.

4. The optical module according to claim 2,
wherein the fourth submount has
a fourth-first surface on which the fourth laser diode is mounted,
a fourth-second surface intersecting the fourth-first surface at right angles, and
a fourth-third surface intersecting the fourth-second surface at right angles and positioned such that a space is formed between the fourth-third surface and the fourth-first surface, and
wherein the fourth submount is mounted on the second substrate such that the fourth-third surface and the second main surface face each other.

5. The optical module according to claim 2,
wherein the center wavelength band of the first light and the center wavelength band of the fourth light are different from each other.

6. An optical module comprising:
a first laser diode configured to emit first light;
a first submount on which the first laser diode is mounted;
a first substrate having a first main surface on which the first submount is mounted; and
a first cap having a first transmission window and hermetically sealed on the first substrate in such a manner as to cover the first laser diode and the first submount, the first transmission window being configured to transmit the first light emitted from the first laser diode,
wherein the first submount has
a first-first surface, and
a first-second surface intersecting the first-first surface at right angles,
wherein the first laser diode is mounted on the first-first surface such that an optical axis direction of the first light is inclined with respect to the first main surface, and
wherein the first submount is mounted on the first substrate such that the first-second surface and the first main surface face each other.

7. The optical module according to claim 6,
wherein the first laser diode has
a first end surface being an end surface located on a side from which the first light is emitted, and
a second end surface located opposite to the first end surface in a direction in which the first light is emitted,
wherein the first end surface has, when viewed in a direction perpendicular to the first end surface,
a first side extending in a thickness direction of the first laser diode and being closer to the first substrate, and
a second side located opposite to the first side, and
wherein, when viewed in a direction perpendicular to the first-first surface, one of the first and second sides overlaps the first-first surface, and another one of the first and second sides projects from the first-first surface.

8. The optical module according to claim 6, further comprising:
a second laser diode configured to emit second light, a center wavelength band of the second light being different from a center wavelength band of the first light; and
a second submount disposed adjacent to the first submount and on which the second laser diode is mounted,
wherein the second submount has
a second-first surface, and
a second-second surface intersecting the second-first surface at right angles,
wherein the second laser diode is mounted on the second-first surface such that an optical axis direction of the second light is inclined with respect to the first main surface, and
wherein the second submount is mounted on the first substrate such that the second-second surface and the first main surface face each other.

9. The optical module according to claim 1,
wherein a circuit pattern electrically connected to the first laser diode is formed on the first substrate.

10. The optical module according to claim 9,
wherein the first submount has a first-fourth surface intersecting the first-first surface at right angles and positioned such that a space is formed between the first-fourth surface and the first-second surface,
wherein a first pad is provided on the first submount in such a manner as to extend on the first-first surface and the first-fourth surface,
wherein the first laser diode is electrically connected to the first pad on the first-first surface by a first wire bonding, and
wherein the circuit pattern is electrically connected to the first pad on the first-fourth surface by a second wire bonding.

11. The optical module according to claim 9,
wherein a first pad is provided on the first submount in such a manner as to extend on the first-first surface and the first-second surface,
wherein the first laser diode is electrically connected to the first pad on the first-first surface by a first wire bonding, and
wherein the circuit pattern is electrically connected to the first pad on the first-second surface by being brought into contact with the first pad with an electrically conductive material interposed between the circuit pattern and the first pad.

12. A light control device comprising:
the optical module according to claim 1; and
a mirror driving mechanism disposed outside the first space and including a scanning mirror on which the first light is incident, the mirror driving mechanism being configured to scan the scanning mirror.

13. The optical module according to claim 7, further comprising:
a second laser diode configured to emit second light, a center wavelength band of the second light being different from a center wavelength band of the first light; and
a second submount disposed adjacent to the first submount and on which the second laser diode is mounted,
wherein the second submount has
a second-first surface, and
a second-second surface intersecting the second-first surface at right angles,
wherein the second laser diode is mounted on the second-first surface such that an optical axis direction of the second light is inclined with respect to the first main surface, and
wherein the second submount is mounted on the first substrate such that the second-second surface and the first main surface face each other.

14. The optical module according to claim 6,
wherein a circuit pattern electrically connected to the first laser diode is formed on the first substrate.

15. A light control device comprising:
the optical module according to claim 6; and
a mirror driving mechanism disposed outside the first space and including a scanning mirror on which the first light is incident, the mirror driving mechanism being configured to scan the scanning mirror.
